(19) United States
(12) Patent Application Publication
(10) Pub. No.: US 2011/0256700 A1
(43) Pub. Date: Oct. 20, 2011

(54) METHOD OF FABRICATING SEMICONDUCTOR DEVICE

(76) Inventors: Chong-Kwang Chang, Bupyeong-gu (KR); Sung-Hon Chi, Seoul (KR); Young-Mook Oh, Hwaseong-si (KR); Ju-Beom Yi, Suwon-si (KR)

(21) Appl. No.: 13/087,522

(22) Filed: Apr. 15, 2011

(30) Foreign Application Priority Data
Apr. 15, 2010 (KR) 10-2010-0034777

(51) Int. Cl. H01L 21/28

(52) U.S. Cl. 438/585; 257/E21.158

(57) ABSTRACT

A method of fabricating a semiconductor device capable of simplifying a fabrication process is provided. The method includes providing a substrate on which first and second regions are defined, forming an interlayer insulating film including first and second trenches on the substrate, the first and second trenches being formed in the first and second regions, respectively, forming a work function adjusting metal film on an upper surface of the interlayer insulating film, side and bottom surfaces of the first trench, and side and bottom surfaces of the second trench, forming a mask film on the interlayer insulating film to fill in the first and second trenches, the mask film including a developable material, forming a mask pattern by developing the mask film, the mask pattern exposing the work function adjusting metal film formed in the first region, removing the work function adjusting metal film formed in the first region by using the mask pattern, removing the mask pattern, and forming a first metal gate in the first trench and a second metal gate in the second trench.

### CROSS-REFERENCE TO RELATED APPLICATION

This application claims priority and all the benefits accruing therefrom under 35 U.S.C. 119 from Korean Patent Application No. 10-2010-0034777 filed on Apr. 15, 2010 in the Korean Intellectual Property Office, the contents of which in their entirety are herein incorporated by reference.

### BACKGROUND

1. Field

The present disclosure relates to a method of fabricating a semiconductor device, and more particularly to a method of fabricating a metal gate.

2. Description of the Related Art

Recently, a metal gate has been frequently used instead of a polysilicon gate in order to improve semiconductor device characteristics. The metal gate may be fabricated by using a replacement metal gate process. However, the replacement metal gate process requires several etching, deposition, and polishing steps, and thus complicates a fabrication process.

### SUMMARY

The disclosed embodiments provide a method of fabricating a semiconductor device capable of simplifying a fabrication process.

The embodiments disclosed herein are not limited thereto, and the other objects of the disclosed embodiments will be described in or be apparent from the following description of the embodiments.

According to one embodiment, a method of fabricating a semiconductor device including is disclosed. The method includes providing a substrate on which first and second regions are defined, forming an interlayer insulating film including first and second trenches on the substrate, the first and second trenches being formed in the first and second regions, respectively, forming a work function adjusting metal film on an upper surface of the interlayer insulating film, side and bottom surfaces of the first trench, and side and bottom surfaces of the second trench, forming a mask film on the interlayer insulating film to fill in the first and second trenches, the mask film including a developable material, forming a mask pattern by developing the mask film, the mask pattern exposing the work function adjusting metal film formed in the first region, removing the work function adjusting metal film formed in the first region by using the mask pattern, removing the mask pattern, and forming a first metal gate in the first trench and a second metal gate in the second trench.

According to another embodiment, a method of fabricating a semiconductor device is disclosed. The method includes providing a substrate including first and second regions, forming first and second sacrificial gates in the first and second regions, respectively, forming an interlayer insulating film to cover the first and second sacrificial gates, planarizing the interlayer insulating film to expose upper surfaces of the first and second sacrificial gates, forming first and second trenches in the first and second regions, respectively, by removing the first and second sacrificial gates, forming a titanium nitride (TiN) film on an upper surface of the interlayer insulating film, side and bottom surfaces of the first trench, and side and bottom surfaces of the second trench, forming a developable bottom anti-reflective coating (DBARC) film on the TiN film to fill in the first and second trenches, forming a photoresist film on the DBARC film, forming a photoresist pattern and a DBARC pattern and developing the photoresist film and the DBARC film to expose the TiN film formed in the first region, removing the TiN film formed in the first region by using the photoresist pattern and the DBARC pattern, removing the photoresist pattern and the DBARC pattern, and forming a first metal gate in the first trench and a second metal gate in the second trench.

According to another embodiment, a method of forming metal gates in a semiconductor device including a substrate including at least first and second regions is disclosed. The method includes forming an interlayer insulating film including first and second trenches on the substrate, the first and second trenches being formed in the first and second regions, respectively, forming a metal film on each of the first trench and the second trench, forming a mask film on the interlayer insulating film to fill in the first and second trenches, the mask film including a developable material, forming a mask pattern by developing the mask film, the mask pattern exposing the metal film formed in the first region, removing the metal film formed in the first region by using the mask pattern, removing the mask pattern, and forming a first metal gate in the first trench and a second metal gate in the second trench.

Other aspects of the disclosed embodiments are included in the detailed description and drawings.

### BRIEF DESCRIPTION OF THE DRAWINGS

The above and other aspects and features of the disclosure will become more apparent by describing in detail exemplary embodiments thereof with reference to the attached drawings, in which:

FIGS. 1 to 7 are diagrams for explaining a method of fabricating a semiconductor device in accordance with an exemplary embodiment;

FIG. 8 is a diagram for explaining a method of fabricating a semiconductor device in accordance with another exemplary embodiment; and

FIGS. 9 to 11 are diagrams for explaining a method of fabricating a semiconductor device in accordance with still another exemplary embodiment.

### DETAILED DESCRIPTION OF THE EMBODIMENTS

Advantages and features disclosed herein, and methods of accomplishing the same may be understood more readily by reference to the following detailed description of exemplary embodiments and the accompanying drawings. The present disclosure may, however, be embodied in many different forms and should not be construed as being limited to the embodiments set forth herein. In the drawings, sizes and relative sizes of layers and regions may be exaggerated for clarity.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present. Like numbers refer to like elements throughout. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, the disclosed embodiments should not be construed as limited to the particular shapes of areas illustrated herein but are to include deviations in shapes that result, for example, from manufacturing. Thus, the areas illustrated in the figures are schematic in nature and their shapes are not intended to illustrate the actual shape of an area of a device and are not intended to limit the scope of the disclosure.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

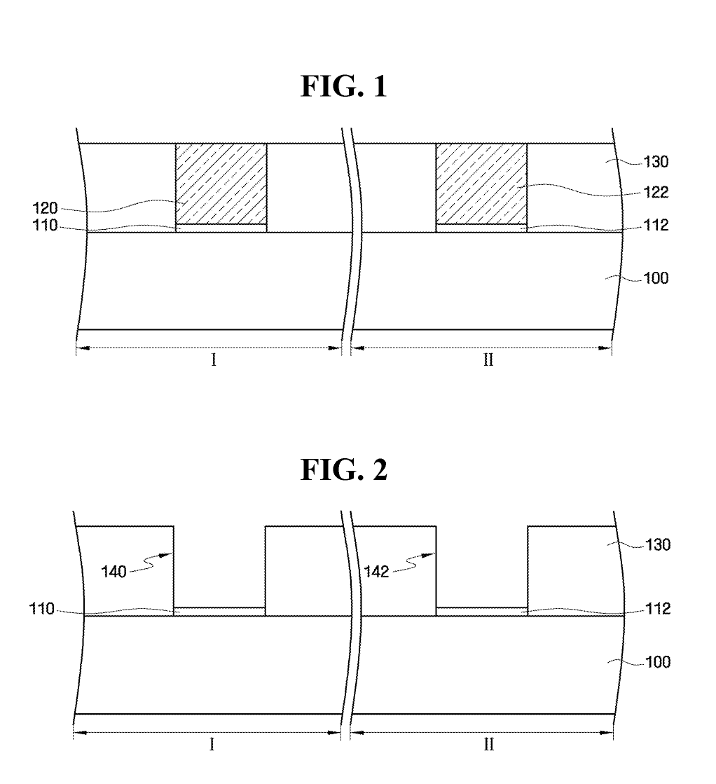

FIGS. 1 to 7 are diagrams for explaining a method of fabricating a semiconductor device in accordance with an exemplary embodiment. In FIGS. 1 to 7, for simplicity, certain regions, such as a device isolation region such as shallow trench isolation (STI) and source/drain regions formed in a substrate and the like are omitted. The embodiments disclosed herein are suitable for use with different types or configurations of device isolation regions, shallow trench isolation regions, and source/drain regions. In addition, the embodiments disclosed herein may be employed in manufacturing many types of semiconductor devices, such as, for example, a semiconductor memory device, a microprocessor device, or other devices that employ semiconductor technology.

Referring to FIG. 1, a first region I and a second region II are defined in a substrate 100. In one embodiment, the first and second regions may be opposite-type regions. For example, the first region I may be an NMOS region and the second region II may be a PMOS region.

In one embodiment, the substrate 100 may be a bulk silicon substrate or a silicon-on-insulator (SOI) substrate. Alternatively, the substrate 100 may be a silicon substrate or may include other materials such as, but not limited to, germanium, indium antimonide, lead telluride, indium arsenide, indium phosphide, gallium arsenide, or gallium antimonide.

A first gate insulating film 110 and a first sacrificial gate 120 are formed on the first region I of the substrate 100, and a second gate insulating film 112 and a second sacrificial gate 122 are formed on the second region II of the substrate 100.

The first sacrificial gate 120 and the second sacrificial gate 122 may be formed of a semiconductor material such as polysilicon. Further, both the first sacrificial gate 120 and the second sacrificial gate 122 may not be doped, or may be doped with similar materials. Alternatively, one of the first sacrificial gate 120 and the second sacrificial gate 122 may be doped, and the other thereof may not be doped. Alternatively, one of the first sacrificial gate 120 and the second sacrificial gate 122 may be doped with a first type material (e.g., an n-type material, such as arsenide, phosphorus or the like) and the other thereof may be doped with a second, opposite-type material (e.g., a p-type material, such as boron or the like).

Each of the first gate insulating film 110 and the second gate insulating film 112 may include a silicon oxide film or high dielectric constant (high-k) material. In other words, each of the first gate insulating film 110 and the second gate insulating film 112 may be a single film of a silicon oxide film or high dielectric constant (high-k) material, or a laminated film including a silicon oxide film and a high-k material.

In one embodiment, the high-k material may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but it is not limited thereto.

An interlayer insulating film 130 may be formed on the substrate 100 to surround and/or cover the first sacrificial gate 120 and the second sacrificial gate 122. The interlayer insulating film 130 may include silicon dioxide, or a low dielectric constant (low-k) material. The interlayer insulating film 130 may be doped with phosphorus, boron or another element and may be formed by high density plasma deposition.

Subsequently, the interlayer insulating film 130 is planarized to expose upper surfaces of the first and second sacrificial gates 120 and 122 by using, e.g., a chemical mechanical polishing (CMP) process.

Referring to FIG. 2, in a subsequent step, the first and second sacrificial gates 120 and 122 are removed to form first and second trenches 140 and 142.

For example, the first and second sacrificial gates 120 and 122 may be removed by wet etching or dry etching. In case of wet etching, the first and second sacrificial gates 120 and 122 may be substantially removed by being exposed to an aqueous solution including a hydroxide source at a sufficient temperature for a sufficient period of time. For example, the hydroxide source may include, but is not limited to, ammonium hydroxide or tetraalkyl ammonium hydroxide such as tetramethylammonium hydroxide (TMAH).

After the first and second sacrificial gates 120 and 122 are removed, the first gate insulating film 110 and the second gate insulating film 112 are exposed.

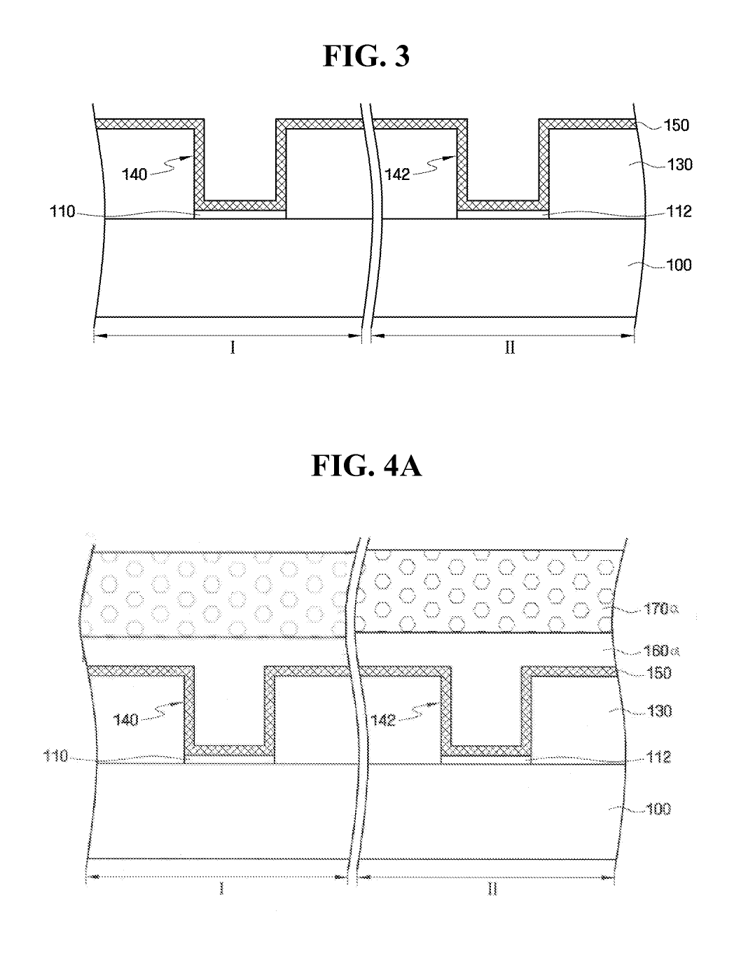

Referring to FIG. 3, a work function adjusting metal film 150 is formed on an upper surface of the interlayer insulating film 130, side and bottom surfaces of the first trench 140, and side and bottom surfaces of the second trench 142.

Specifically, because the first gate insulating film 110 and the second gate insulating film 112 remain, the work function adjusting metal film 150 may be formed on the upper surface of the interlayer insulating film 130, the side surface of the first trench 140, an upper surface of the first gate insulating film 110, the side surface of the second trench 142 and an upper surface of the second gate insulating film 112.

The work function adjusting metal film 150 may include, for example, titanium nitride (TiN). A conduction band of TiN has a work function of about 4.2 eV to 4.5 eV.

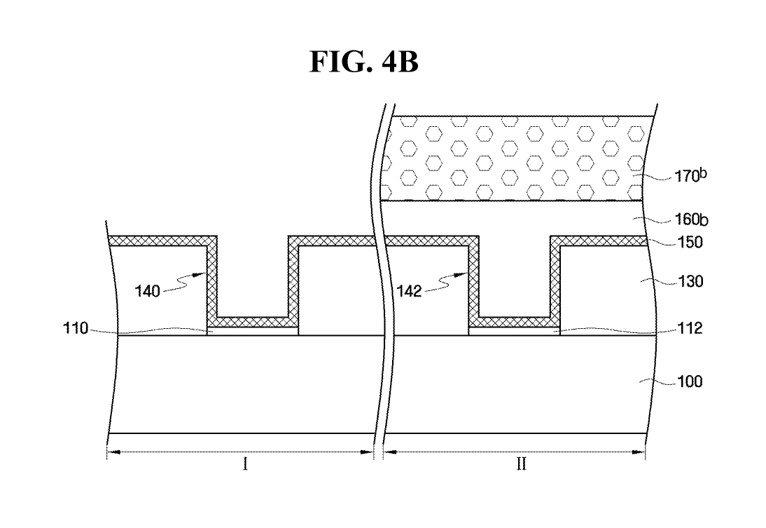

Referring to FIG. 4A, a mask film 160a may be formed on the interlayer insulating film 130 and may fill in the first and second trenches 140 and 142.

In one embodiment, the mask film may be formed of a developable material, e.g., a developable bottom anti-reflective coating (DBARC). Further, the mask film may be formed of a material having excellent gap-fill characteristics to be easily formed in the first and second trenches 140 and 142.

Then, a photoresist film 170a may be formed on the mask film.

In order to perform an etching process, a mask film should have a sufficient thickness to endure etching. However, the mask film used in this embodiment is formed of a developable material (e.g., DBARC), which may be difficult to form to have a sufficient thickness depending on a fabrication process. Accordingly, the photoresist film may be further formed on the mask film, and therefore two layers including the mask film and the photoresist film are used in the etching process. In one embodiment, the mask film and the photoresist film have a total thickness sufficient to endure etching. In one embodiment, if the mask film has a sufficient thickness, the photoresist film may be omitted.

Subsequently, in one embodiment as depicted in FIG. 4B, mask film 160a and photoresist film 170a are developed at the same time to form a mask pattern 160b and a photoresist pattern 170b. The mask pattern 160b and the photoresist pattern 170b may include a pattern that covers the work function adjusting metal film 150 formed in the second region II, but exposes the work function adjusting metal film 150 formed in the first region I.

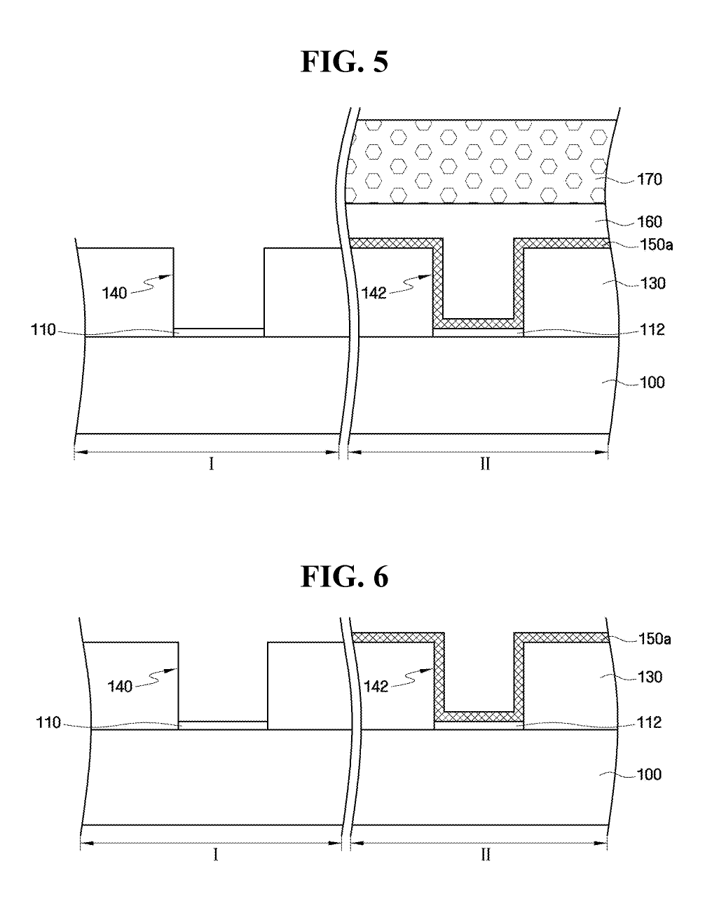

Referring to FIG. 5, based on the mask pattern 160b and photoresist pattern 170b, the work function adjusting metal film 150 formed in the first region I is removed, and a work function adjusting metal film 150a remains only in the second region II.

When the work function adjusting metal film 150 formed in the first region I is removed, the first gate insulating film 110 is exposed in the first trench 140 of the first region I.

In one embodiment, the work function adjusting metal film 150 may be removed by wet etching in order to cause minimal damage to the first gate insulating film 110, which is exposed during removal of the work function adjusting metal film 150.

Referring to FIG. 6, in a subsequent step, the mask pattern 160b and the photoresist pattern 170b may be removed, for example, at the same time.

For example, the mask pattern 160b and the photoresist pattern 170b may be removed by using an oxygen-free ashing process. In the case of using an oxygen-free ashing process, it is possible to reduce damage to the exposed first gate insulating film 110.

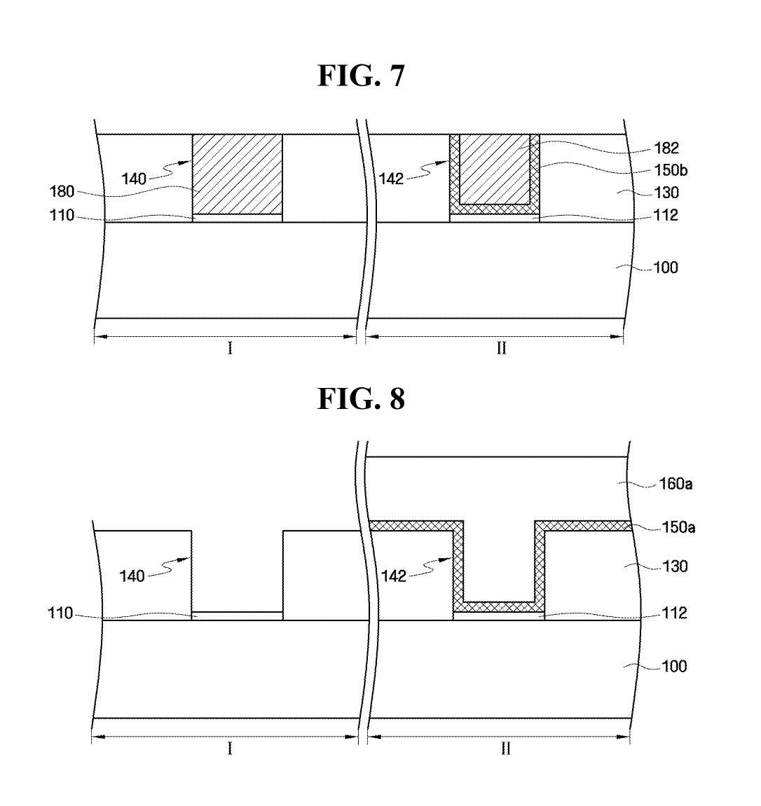

Referring to FIG. 7, a first metal gate 180 is formed to fill in the first trench 140.

A second metal gate 182 is formed to fill in the second trench 142.

For instance, a metal film (not shown) may be formed to sufficiently fill in the first trench 140 and the second trench 142. The metal film is may be then planarized to expose the upper surface of the interlayer insulating film 130, thereby forming the first metal gate 180 and the second metal gate 182.

In one embodiment, since the planarization is performed to expose the upper surface of the interlayer insulating film 130, the work function adjusting metal film 150a remaining on the upper surface of the interlayer insulating film 130 in the second region II is removed. Accordingly, a work function adjusting metal film 150b is formed only in the second trench 142.

The first metal gate 180 and the second metal gate 182 may include at least one of tungsten (W), aluminum (Al) and copper (Cu), which can have different work functions from the work function adjusting metal film.

Consequently, in the first region I, the first gate insulating film 110 is formed on the bottom surface of the first trench 140, and the first metal gate 180 is formed to fill in the first trench 140.

On the other hand, in the second region II, the second gate insulating film 112 is formed on the bottom surface of the second trench 142, and the work function adjusting metal film 150b is formed on the side surface of the second trench 142 and the bottom surface of the second trench 142 (i.e., the upper surface of the second gate insulating film 112). The second metal gate 182 is formed on the work function adjusting metal film 150b to fill in the second trench 142. Since the work function adjusting metal film 150b is formed only in the second region II, a work function of the gate formed in the first region I is different from a work function of the gate formed in the second region II.

In the above embodiment, since a developable material is used as the mask film, the fabrication process is simplified. Namely, the mask film can be patterned only by development without an additional etching process (see, e.g., FIG. 5). Further, the photoresist pattern and the mask pattern can be removed at the same time (see, e.g., FIG. 6).

On the other hand, if a non-developable material (e.g., an oxide film and a nitride film) is used as the mask film, the fabrication process may be more complicated. For example, if an oxide film is used as the mask film, the oxide film is entirely coated on the structure of FIG. 3. Then, the oxide film is planarized and a photoresist film is formed on the planarized oxide film. Then, the photoresist film is developed to form a photoresist pattern, and the oxide film is patterned using the photoresist pattern. Subsequently, the work function adjusting metal film is patterned using the patterned oxide film. Then, the patterned oxide film is removed. In other words, a complicated process must be performed to pattern the work function adjusting metal film.

FIG. 8 is a diagram for explaining a method of fabricating a semiconductor device in accordance with another exemplary embodiment.

Unlike the above-described embodiment in which two layers including the mask pattern 160 and the photoresist pattern 170 are used to etch the work function adjusting metal film 150 (see FIG. 4), in the method of fabricating a semiconductor device of this embodiment, only a layer of a mask pattern 160a is used without the photoresist pattern 170. The thickness of the mask pattern 160a shown in FIG. 8 may be relatively larger than the thickness of the mask pattern 160 shown in FIG. 4.

As shown in FIG. 8, if the mask pattern 160a is formed to have a sufficient thickness to endure etching, the photoresist pattern 170 is unnecessary.

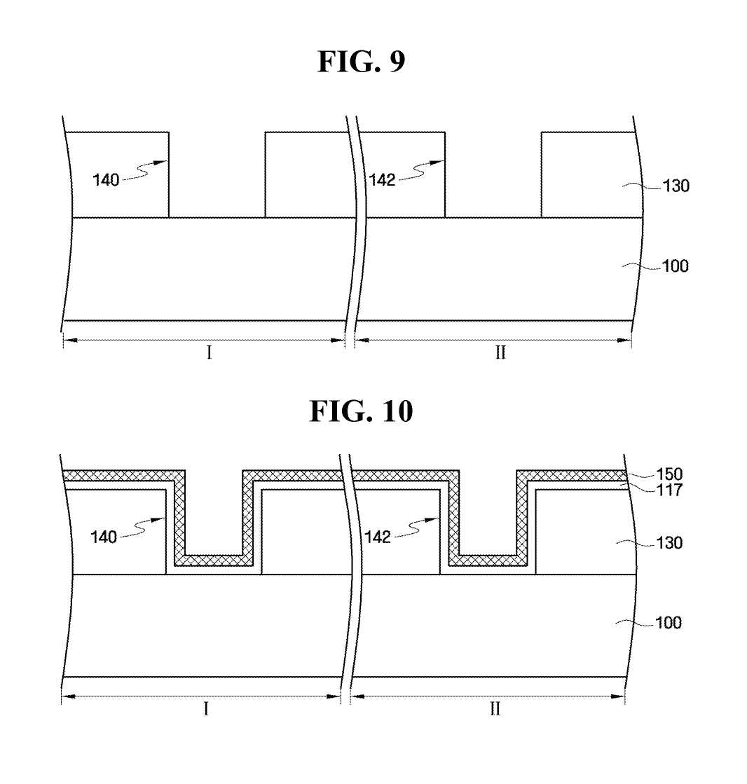

FIGS. 9 to 11 are diagrams for explaining a method of fabricating a semiconductor device in accordance with still another exemplary embodiment. For convenience of explanation, the description will be given focusing on differences between this embodiment and the above-described embodiment.

Referring to FIG. 9, the first sacrificial gate 120 and the second sacrificial gate 122 are removed from the structure of FIG. 1. Then, the first gate insulating film 110 and the second gate insulating film 112 are also removed therefrom.

Referring to FIG. 10, an insulating film 117 is formed on the upper surface of the interlayer insulating film 130, the side and bottom surfaces of the first trench 140, and the side and bottom surfaces of the second trench 142.

Then, the work function adjusting metal film 150 is conformally formed on the insulating film 117.

Subsequently, the work function adjusting metal film 150 formed in the first region I is removed by using the method described with reference to FIGS. 4, 5 and 6.

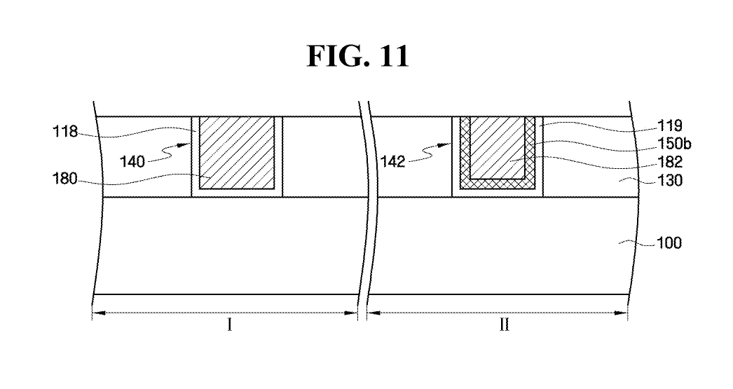

Referring to FIG. 11, the first metal gate 180 is formed to be embedded in the first trench 140, and the second metal gate 182 is formed to be embedded in the second trench 142.

For example, a metal film is formed to be sufficiently embedded in the first trench 140 and the second trench 142. The metal film is planarized to expose the upper surface of the interlayer insulating film 130, thereby forming the first metal gate 180 and the second metal gate 182.

In brief, in the first region I, a third gate insulating film 118 is formed on the bottom and side surfaces of the first trench 140, and the first metal gate 180 is formed to be embedded in the first trench 140.

On the other hand, in the second region II, a third gate insulating film 119 is formed on the bottom and side surfaces of the second trench 142, and the work function adjusting metal film 150b is conformally formed on the third gate insulating film 119. The second metal gate 182 is formed on the work function adjusting metal film 150b to be embedded in the second trench 142.

While the present disclosure has been particularly shown and described with reference to exemplary embodiments thereof, it will be understood by those of ordinary skill in the art that various changes in form and detail may be made therein without departing from the spirit and scope of the present Inventive concept as defined by the following claims. The exemplary embodiments should be considered in a descriptive sense only and not for purposes of limitation.

What is claimed is:

1. A method of fabricating a semiconductor device comprising:
providing a substrate on which first and second regions are defined;
forming an interlayer insulating film including first and second trenches on the substrate, the first and second trenches being formed in the first and second regions, respectively;
forming a work function adjusting metal film on an upper surface of the interlayer insulating film, side and bottom surfaces of the first trench, and side and bottom surfaces of the second trench;
forming a mask film on the interlayer insulating film to fill in the first and second trenches, the mask film including a developable material;
forming a mask pattern by developing the mask film, the mask pattern exposing the work function adjusting metal film formed in the first region;
removing the work function adjusting metal film formed in the first region by using the mask pattern;
removing the mask pattern; and
forming a first metal gate in the first trench and a second metal gate in the second trench.

2. The method of claim 1, wherein the mask film is a developable bottom anti-reflective coating (DBARC) film.

3. The method of claim 1, wherein said forming a mask pattern comprises:
forming a photoresist film on the mask film; and
forming the mask pattern and a photoresist pattern by developing the mask film and the photoresist film.

4. The method of claim 3, wherein said removing the work function adjusting metal film formed in the first region by using the mask pattern comprises removing the work function adjusting metal film formed in the first region by using the mask pattern and the photoresist pattern.

5. The method of claim 3, wherein said removing the mask pattern comprises removing the mask pattern and the photoresist pattern at the same time.

6. The method of claim 5, wherein said removing the mask pattern is performed by using an oxygen-free ashing process.

7. The method of claim 1, wherein the metal film includes titanium nitride (TiN).

8. The method of claim 1, wherein the first region is an NMOS region and the second region is a PMOS region.

9. The method of claim 1, wherein said forming an interlayer insulating film including first and second trenches comprises:
forming first and second sacrificial gates on the substrate, the first and second sacrificial gates being formed in the first and second regions, respectively;
forming the interlayer insulating film on the substrate to cover the first and second sacrificial gates;
planarizing the interlayer insulating film to expose upper surfaces of the first and second sacrificial gates; and
forming the first and second trenches by removing the first and second sacrificial gates.

10. The method of claim 9, wherein a first gate insulating film is positioned between the first sacrificial gate and the substrate, and a second gate insulating film is positioned between the second sacrificial gate and the substrate.

11. The method of claim 10, wherein said removing the work function adjusting metal film is performed by wet etching.

12. The method of claim 10, wherein said forming a work function adjusting metal film comprises forming the work function adjusting metal film on the upper surface of the interlayer insulating film, the side surface of the first trench, an upper surface of the first gate insulating film, the side surface of the second trench, and an upper surface of the second gate insulating film.

13. The method of claim 10, further comprising:
removing the first and second gate insulating films after removing the first and second sacrificial gates; and
forming a separate insulating film on the upper surface of the interlayer insulating film, the side and bottom surfaces of the first trench, and the side and bottom surfaces of the second trench before forming the work function adjusting metal film.

14. A method of fabricating a semiconductor device comprising:
providing a substrate including first and second regions;
forming first and second sacrificial gates in the first and second regions, respectively;
forming an interlayer insulating film to cover the first and second sacrificial gates;
planarizing the interlayer insulating film to expose upper surfaces of the first and second sacrificial gates;
forming first and second trenches in the first and second regions, respectively, by removing the first and second sacrificial gates;
forming a titanium nitride (TiN) film on an upper surface of the interlayer insulating film, side and bottom surfaces of the first trench, and side and bottom surfaces of the second trench;
forming a developable bottom anti-reflective coating (DBARC) film on the TiN film to fill in the first and second trenches;
forming a photoresist film on the DBARC film;
forming a photoresist pattern and a DBARC pattern and developing the photoresist film and the DBARC film to expose the TiN film formed in the first region;
removing the TiN film formed in the first region by using the photoresist pattern and the DBARC pattern;
removing the photoresist pattern and the DBARC pattern; and
forming a first metal gate in the first trench and a second metal gate in the second trench.

15. The method of claim 14, wherein said forming the photoresist pattern and the DBARC pattern is performed by using an oxygen-free ashing process.

16. The method of claim 14, wherein a first gate insulating film is positioned between the first sacrificial gate and the substrate, and a second gate insulating film is positioned between the second sacrificial gate and the substrate, and
said removing the TiN film formed in the first region is performed by wet etching.

17. A method of forming metal gates in a semiconductor device including a substrate including at least first and second regions, the method comprising:
forming an interlayer insulating film including first and second trenches on the substrate, the first and second trenches being formed in the first and second regions, respectively;
forming a metal film on each of the first trench and the second trench;
forming a mask film on the interlayer insulating film to fill in the first and second trenches, the mask film including a developable material;
forming a mask pattern by developing the mask film, the mask pattern exposing the metal film formed in the first region;
removing the metal film formed in the first region by using the mask pattern;
removing the mask pattern; and
forming a first metal gate in the first trench and a second metal gate in the second trench.

18. The method of claim 17, wherein forming the metal film on each of the first trench and the second trench comprises:
forming a work function adjusting metal film on an upper surface of the interlayer insulating film, side and bottom surfaces of the first trench, and side and bottom surfaces of the second trench.

19. The method of claim 18, wherein forming the first metal gate in the first trench and the second metal gate in the second trench includes:
filling the first trench with a first metal and filling the second trench with a second metal,
wherein a conduction band of the work function adjusting metal film has a different work function than the work function of a conduction band of either of the first metal or the second metal.

20. The method of claim 17, further comprising:
forming a photoresist film on the mask film;
forming the mask pattern and a photoresist pattern by developing the mask film and the photoresist film; and
removing the photoresist pattern at the same time as removing the mask pattern.
